(19) United States
(12) Patent Application Publication
(10) Pub. No.: US 2025/0148143 A1
(43) Pub. Date: May 8, 2025

(54) Furring And Cladding Design Matrix And Method Of Using Thereof

(71) Applicant: Starborn Industries, Inc., Edison, NJ (US)

(72) Inventors: Paul Gertner, Brooklyn, NY (US); Steven Checco, Stony Point, NY (US)

(73) Assignee: Starborn Industries, Inc., Edison, NJ (US)

(21) Appl. No.: 18/939,116

(22) Filed: Nov. 6, 2024

Related U.S. Application Data
(60) Provisional application No. 63/547,467, filed on Nov. 6, 2023.

(51) Int. Cl. G06F 30/13; E04F 13/08; G06F 30/27; G06T 7/00; G06T 19/20

(52) U.S. Cl. CPC G06F 30/13; E04F 13/0805; G06F 30/27; G06T 7/0002; G06T 19/20; G06T 2210/04; G06T 2219/024; G06T 2219/2024

(57) ABSTRACT

Disclosed is an entirely new method of installing cladding. The invention is the first comprehensive system for converting square edge boards such as decking into a wide selection of cladding scenarios that can be chosen based on building design, environmental conditions, and aesthetics. It includes decision matrixes for determining optimal choices and configurations for furring strip and cladding board installation.

### CROSS-REFERENCE TO RELATED APPLICATIONS

This application claims the benefit of the filing date of U.S. Provisional Patent Application No. 63/547,467 filed Nov. 6, 2023, the disclosure of which is hereby incorporated herein by reference.

### TECHNICAL FIELD

The present disclosure relates to a furring and cladding design matrix and method of using thereof. Specifically, the disclosure relates to a system and method for affixing cladding to building facades more efficiently and to convert any deck board into cladding.

### BACKGROUND

Rainscreens are an existing form of siding construction where the siding, also referred to as cladding, is spaced off of the building envelope using furring or furring strips for increased ventilation and drainage. The additional ventilation and drainage come with a host of benefits, such as allowing the building to breathe, reducing moisture build-up, and minimizing the formation of mold.

Rainscreens can be either open-joint or closed-joint. While both of these methods are open at the top and bottom of the wall for increased ventilation and drainage, open-joint rainscreens have gaps between the cladding which allows for further ventilation. Closed joint rainscreens have no gaps between boards and in some cases the boards may overlap.

The typical method for spacing the cladding off of the building envelope is with furring strips. These are usually wooden strips, metal z-girts, or metal hat channels, however other, less-common types exist made from plastics or fiberglass. These furring strips are fastened back to the building stud and, in some cases, are responsible for holding the weight of whatever cladding is going on the building. Given the variety of options available for rainscreen construction, it is paramount that the correct fastening methods are used when both designing and installing a rainscreen.

Deck board manufacturers have already taken notice of this growing trend, with some companies even offering new boards specifically for cladding applications.

However, the market is still lacking proper education to the consumer on the best installation practices for using these PVC and composite boards as a form of siding, and the same holds true for hardwood boards. Based on factors such as the predesigned building construction, the desired cladding board, the desired of type furring strip, and the amount of exterior insulation required, there can be a plethora of combinations and configurations for the rainscreen assembly. However not all rainscreen configurations are practical or structurally sound. While the market for using PVC, composite, and hardwood boards as cladding is still in its early stages, it is imperative that architects and contractors are informed on the best installation practices with these materials.

The last ten years have seen the increased use of open joint rain screens for cladding both commercial and residential buildings. This style of cladding has made it possible to use square edged deck boards for cladding, which has become an emergent trend in new building design. The trend is largely being driven by aesthetics. Decking comes in a much wider range of choices than currently available siding products, such as, colors, textures, and materials.

The use of decking for siding offers a certain aesthetic that is increasingly in vogue. The problem faced by the market is that there is a lack of information on how to adapt decking as cladding. In particular, there is market confusion about what hardware components are needed to do this installation.

Again, there is currently no solution for the problem faced by the market. There is a lack of information on how to adapt decking and similar square edge boards as cladding. In particular, there is market confusion about what hardware components are needed to do this installation.

Therefore, there is a need for an improved system and method to provide installers with decking material and hardware component selection along with proper installation instructions for cladding the facade of a building and avoiding the above disadvantages.

### SUMMARY

Compared to prior attempts in the art, the present disclosure fulfills the above criteria and provides additional benefits that state of the art systems cannot provide. Disclosed and described is a system and method that secures cladding even if the cladding material is a decking material. The invention is a combination of information and components that give an installer everything they need to use decking as cladding. It is a turnkey approach that enables any installer to convert any deck board into cladding.

One objective is to provide a Cladding Design method to guide designers and builders through a comprehensive process for using deck boards as cladding.

Another objective is to provide a method using an indexed list of deck and similar boards that are suitable for cladding.

Another objective is to provide selection matrixes for cladding fasteners and related hardware. These matrixes are the first comprehensive design guidelines encompassing all deck to cladding scenarios including fastener and furring strip selection.

Yet another objective is to provide a Furring Design Matrix. The Furring Design Matrix educates architects, contractors, and homeowners on the proper fastening methods for tying the furring back to the building structure based on the specific construction of the building. Depending on the existing building construction, the desired furring strip, and the thickness of exterior insulation, the matrix recommends the best structural fastener for the installation.

Another objective is to provide a Cladding Design Matrix. Once a deck board has been selected for use as cladding, the Cladding Design Matrix supplies the end user with a how to choose guide from the many types of fasteners and furring strips they will need to complete their installation.

Also provided is a cladding fastener selection. The selection is the first comprehensive fastener selection for all deck to cladding scenarios. It includes fasteners to attach furring strips to the building as well as fasteners to attach deck boards to the furring strips. This selection is the first comprehensive fastener selection for all deck to cladding scenarios. It includes fasteners to attach furring strips to the building as well as fasteners to attach deck boards to the furring strips.

Still another objective is to provide a Cladding Visualizer Tool. This tool is a visualization tool, where designers can input vertical building profiles and pick for a huge number of deck board choices and place them on various portions of their design.

In one aspect an electronic tool is a visualization tool on a computer, software application, personal electronic device, or the like. Designers or users can input vertical building profiles or have the application scan in various profiles based upon the need of the user. Further included may be a system or a non-transitory computer readable storage medium comprising storage, retrieval, modification, measurement and linking system software which instructs at least one computer processor residing on a specialized computer system to implement a process to link at least one storage device to real time data from at least one internet disseminated electronic data stream where the at least one internet disseminated electronic data stream includes collective data regarding at least one aspect of the project implementation. The at least one aspect is selected from a group consisting of a wall material construction, a sheathing thickness, an exterior insulation thickness, a structural furring variable, a non-structural furring variable, an environmental condition, and any combination thereof.

These objectives and aspects and many more are further described, shown, and discussed in the attached drawings and following detailed descriptions.

### BRIEF DESCRIPTION OF THE DRAWINGS

To assist those of skill in the art in making and using the disclosed composition and method, reference is made to the accompanying figures, wherein:

FIG. 1 shows one embodiment of a Cladding Design Method which explains to designers and installers the entire cladding design process and various subprocesses which they can utilize for successful use of deck or similar boards for cladding.

FIG. 2 shows one embodiment of the present invention that utilizes a Board Suitability Table.

FIG. 3 illustrates an example of one embodiment of the present invention that utilizes the Cladding Visualizer;

FIG. 4 shows an illustrative design of one embodiment of the present invention that utilizes a Furring Design Matrix;

FIG. 5 illustrates one embodiment of the present invention that utilizes a Cladding Design Matrix;

### DETAILED DESCRIPTION

The invention includes, according to certain embodiments, systems and processes relates to a fixation device used in applying decking material and/or other material to the face of a building. As known in the art, rainscreens are an existing form of siding construction where the siding, also referred to as cladding, is spaced off of the building envelope using furring for increased ventilation and drainage. The additional ventilation and drainage come with a host of benefits, such as allowing the building to breathe, reducing moisture build-up, and minimizing the formation of mold.

A typical method for spacing cladding off of the building envelope is with “furring strips.” These are usually wooden strips, metal z-girts, or metal hat channels, however other, less-common types exist made from plastics or fiberglass. These furring strips are fastened back to the building stud and, in some cases, are responsible for holding the weight of whatever cladding is going on the building. Given the variety of options available for rainscreen construction, it is paramount that the correct fastening methods are used when both designing and installing a rainscreen.

The current state of the art is still lacking proper education to the consumer on the best installation practices for using these PVC, composite, and hardwood boards as a form of siding. Based on factors such as the predesigned building construction, the desired cladding board, the desired of type furring strip, and the amount of exterior insulation required, there can be a plethora of combinations and configurations for the rainscreen assembly. However not all rainscreen configurations are practical or structurally sound. While the market for using PVC, composite and hardwood boards as cladding is still in its early stages, it is imperative that architects and contractors are informed on the best installation practices with these materials.

In addition, grooved deck boards are generally used with clips. The current inventors do not believe current clips are strong enough for exterior use. However, they can be incorporated into our cladding system for using deck boards to clad both interior walls and ceilings.

The furring strip depending on the implementation may be made of various materials including but not limited to metal, plastic, fiberglass, fiber, composite, wood, concrete, and the like. The various materials and flexibility of design of the current invention is useful where metal furring strips are not usable due to exposure to salt water, for example.

The present inventors have discovered, among other things, a cladding Fastener Selection. The present inventors started with a selection of deck fasteners and added two novel items. This method is the first comprehensive fastener selection for all deck to cladding scenarios. It includes fasteners to attach furring strips to the building as well as fasteners to attach deck boards to the furring strips.

To overcome design challenges that state of the art technology could not overcome, the inventors devised a Cladding Design Method that includes a Flow Chart which encompasses the entire design process for choosing to use a deck or similar boards as a form of siding.

The inventors also disclose a Board Suitability Table which allows a user to know which boards on the market are available for use in a cladding application. The Board Suitability Table also provides information about the board such as its thickness and material which are necessary for proper installation.

Utilizing a computer or digital instrument, a user may utilize a Cladding Visualizer Tool. This tool is a visualization tool where designers inputs vertical building profiles and pick for a large number of deck board choices and place them on various portions of their design.

A system, method, and a computer readable medium that decreases computer processing time to market conditions required by designers to minimize and redirect inaccuracies in selection of furring cladding and screw fasteners. The disclosed system, method, and computer readable medium may be utilized across a wide range of environments where cladding may be installed in various climates and environments needing special attention to material selection and fastener selection.

In contrast to current systems and methods, the present innovation considers all parameters involved in the installation process including local and global building codes and regulations in addition to other variables currently not being addressed, which is addressed in the present innovation. For example, the current innovation provides options based upon building design giving the designer options beyond the designers requirements. In addition, the present process decides on the structural screw required, not only based on mechanical and physical properties, but also upon aesthetic requirements, building codes and regulations, and other variables such as but not limited to environmental conditions not ordinarily considered. Such environmental conditions may include but is not limited to, marine (water) applications, desert (heat and dryness) applications, high altitude applications, cold and frost applications, and any combination thereof.

The specialized system and processes may include a specialized machine such as a server to provide a software application on a personal device. The server depicts a network, machine computer, processor in communication with or including an image storage/retrieval system or a database of content as described herein. The server, when specifically operating in accordance with the principles of the disclosed embodiment operates as a receiver, translator, processor, filter, storage, and distributor of content related data. The server receives content from content providers, and responds to requests, electronic trading order flows, and administrator settings. The server automatically processes data relating to the system modification of the cladding, furring and fastener selections according to a designer's interest and/or interests of the surrounding environment as selected by a user and/or artificial intelligence (AI) provided by the specialized system and processes. The server may be independent such as an off-site server, or its components and features may be incorporated into a computer site or into features offered by the present invention. In conjunction with the present application the term “user” refers to without limitation any user, designer, builder, and the like in combination with the presently disclosed specialized computer software, artificial intelligence, software application, process, method, system, non-transitory computer medium, and the like and/or only any user alone and/or only the presently disclosed specialized computer software, artificial intelligence, software application, process, method, system, non-transitory computer medium alone.

In furtherance with the present disclosure, the inventors also disclose a Cladding Design Matrix. Once a deck board has been selected for use as cladding, the Cladding Design Matrix supplies the end user with a how to choose guide with workable options from the many types of fasteners and furring strips they will need to complete their installation.

In the inventor's Furring Design Matrix, the Furring Design Matrix educates architects, contractors, and homeowners on the proper fastening methods for tying the furring back to the building structure based on the specific construction of the building. Depending on the existing building construction, the desired furring strip, and the thickness of exterior insulation, the matrix recommends the best structural fastener for the installation.

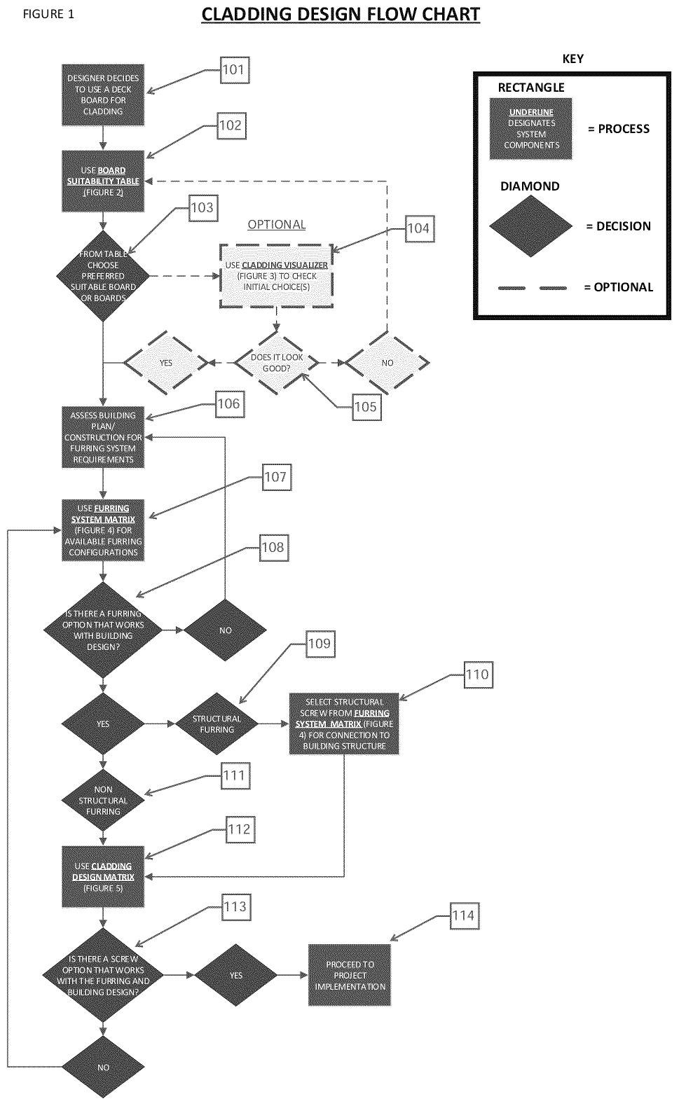

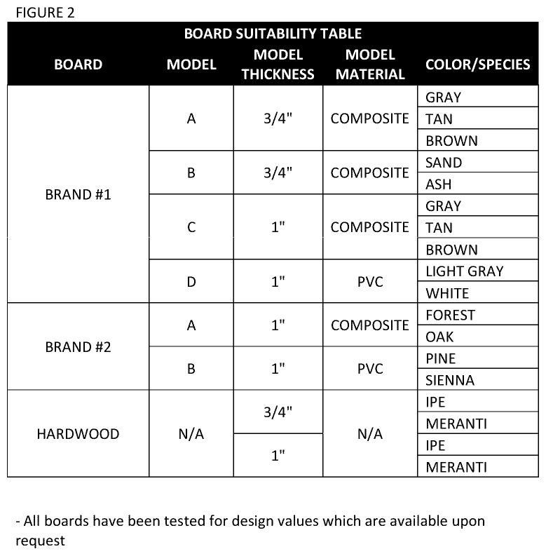

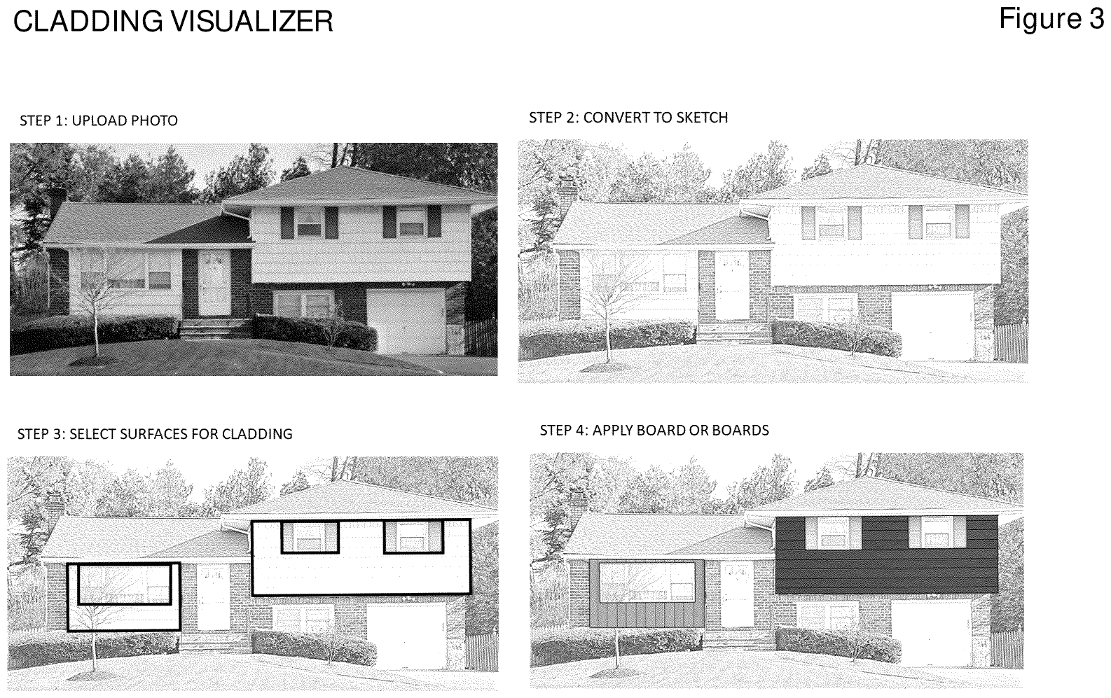

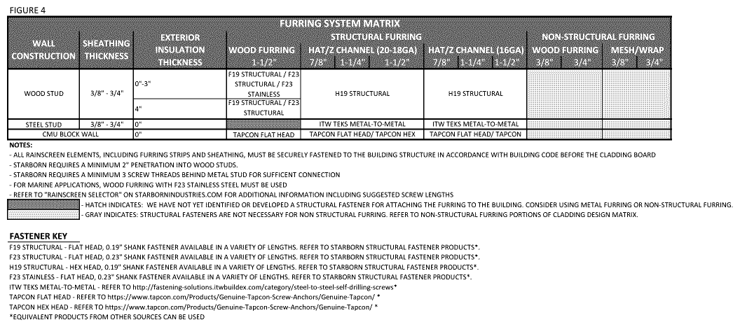

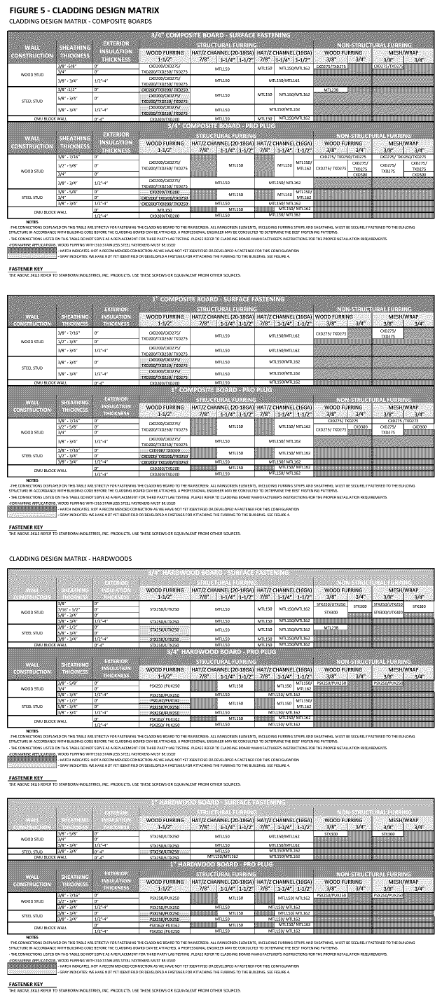

Adverting to the Figures, FIG. 1 illustrates a flow chart on how to utilize each of the components in the invention. As shown in block 101 the first step is choosing a deck board for cladding, Block 102 is using the Board Suitability Table (FIG. 2). Block 103 is choosing a preferred deck board. Block 104 may or may not be optional. It is using the Cladding Visualizer (FIG. 3). Block 105 is to determine if the selected board on the Cladding Visualizer is aesthetically acceptable. Block 106 is an assessment of the building plan and construction for furring system requirements. Block 107 is using the Furring System Matrix (FIG. 4). Block 108 provides determination of whether a furring option works with the building design. Block 109 provides next steps if structural furring is being used. Block 110 provides a selection of compatible structural fastener or fasteners in cases where structural furring is being used. Block 111 provides the next steps if nonstructural furring is being used. Block 112 is using the Cladding Design Matrix (FIG. 5). Block 113 identifies screw options that works with the furring and building design. Block 114 is proceeding with project implementation.

FIG. 2 illustrates an example of the Board Suitability Table. The user uses this table to understand which deck or similar boards are available for use in a cladding application as well as notable features about said boards such as board thickness and material.

FIG. 3 illustrates an embodiment of the Cladding Visualizer. The Cladding Visualizer is a digital tool in which a user uploads an image of their building façade and superimposes different types of cladding boards on the façade.

FIG. 4 illustrates a Furring Design Matrix. This Furring Design Matrix allows for a selection of wall constructions sheathing thickness and exterior insulation thickness. Depending on the wood furring dimensions and type of channel a specific fastener is selected. The user would first assess their existing building construction, which is often predetermined. Based on the initial building construction, the user then determines if they are using a structural or non-structural furring strip. If they are using a structural furring strip, the matrix will determine which structural fastener they should select to tie the furring back to the building structure before continuing to the Cladding Design Matrix (FIG. 5). If the user is using a non-structural furring strip, they should continue to the Cladding Design Matrix (FIG. 5).

FIG. 5 illustrates one embodiment of a Cladding Design Matrix. Shown and described is a ¾ inch composite board surface fastening table and Pro Plug table. [Also shown is a 1 inch composite board surface fastening and Pro Plug table. The matrix allows for a selection of wall construction sheathing thickness and exterior insulation thickness. Depending on the wood furring dimensions and type of channel a specific fastener is selected. The user and/or software and/or artificial intelligence (AI) would first assess the material and thickness of the board that will be used and then directed to the proper table on the matrix. This information can be referenced from the Board Suitability Table on FIG. 2. The user would then assess their existing building construction, which is often predetermined. The user would then determine the type of furring chosen from the Furring Design Matrix on FIG. 4. Based on all of these assessments, the matrix will provide the correct fastener guidance for mounting specific boards as a form of cladding.

Any headings and sub-headings utilized in this description are not meant to limit the embodiments described thereunder. Features of various embodiments described herein may be utilized with other embodiments even if not described under a specific heading for that embodiment.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

While exemplary embodiments have been described herein, it is expressly noted that these embodiments should not be construed as limiting, but rather that additions and modifications to what is expressly described herein also are included within the scope of the invention. Moreover, it is to be understood that the features of the various embodiments described herein are not mutually exclusive and can exist in various combinations and permutations, even if such combinations or permutations are not made express herein, without departing from the spirit and scope of the invention.

What is claimed is:

1. A method for installing furring and cladding using fasteners, comprising the steps of:
selecting a deck or other square edged board for cladding;
determining if a board is suitable for cladding by a board suitability table;
providing an assessment of a building plan and construction regulations for furring system requirements;
using a furring system matrix for making a comparison;
determining whether a furring option works with the building design;
if using a structural furring then selecting a structural screw or fastener to a furring back to a selected building structure;
using cladding design matrix and determining if using a nonstructural furring;
determining if there is a screw option that works with the furring and a building design; and
proceeding with a project implementation.

2. The method of claim 1, wherein the selecting step is done on a cladding visualizer tool.

3. The method of claim 2, wherein the tool is a visualization tool where designers or users can input vertical building profiles.

4. The method of claim 3, further includes picking a deck board and placing the deck board on various portions of a design.

5. The method of claim 4, wherein the picking step is accomplished by artificial intelligence (AI) based upon at least building codes, and design requirements.

6. The method of claim 3, further includes using a non-transitory computer readable storage medium comprising storage, retrieval, modification, measurement and linking system software which instructs at least one computer processor residing on a specialized computer system to implement a process to link at least one storage device to real time data from at least one internet disseminated electronic data stream where the at least one internet disseminated electronic data stream includes collective data regarding at least one aspect of the project implementation.

7. The method of claim 6, wherein the collective data regarding at least one aspect is selected from a group consisting of a wall material construction, a sheathing thickness, an exterior insulation thickness, a structural furring variable, a non-structural furring variable, an environmental condition, and any combination thereof.

8. The method of claim 7, wherein the environmental condition include a marine application.

9. The method of claim 7, wherein the structural furring variable includes a type of material of a furring, dimensions of a channel in the furring, thickness gauge of the furring, and any combination thereof.

10. The method of claim 7, wherein the non-structural variable includes type of a furring or mesh/wrap.

11. A method for installing cladding using fasteners, comprising the steps of:
choosing a deck or other square edged board for cladding;
comparing on a board suitable table to determine if a board is suitable for a cladding;
determining if using a nonstructural furring is required and then utilizing a cladding design matrix to select the cladding;
determining if there is a screw fastener option that is compatible with the cladding and building design; and
proceeding with project implementation.

12. The method of claim 11, wherein the choosing step is accomplished by a user, artificial intelligence (AI), or a combination of the user and AI.

13. The method of claim 11, wherein the board suitable table is determined by a user, artificial intelligence (AI), or a combination of the user and AI.

14. The method of claim 11, wherein the screw fastener option determination further includes evaluating aesthetic requirements, building codes and regulations, structural requirements, evaluation of environmental conditions, and any combination thereof,

15. The method of claim 11, further includes utilizing a system having a memory device, the memory device further including a Random Access Memory (RAM) a processor connected to the memory device, the processor configured to linking at least one storage device to real time data from at least one internet disseminated electronic data stream where the at least one internet disseminated electronic data stream includes collective data regarding at least one aspect of the project implementation.

16. The method of claim 11, wherein the real-time data includes a structural furring variable, a non-structural furring variable, an environmental condition, and any combination thereof.

17. The method of claim 11, wherein the collective data regarding at least one aspect is selected from a group consisting of a wall material construction, a sheathing thickness, an exterior insulation thickness, a structural furring variable, a non-structural furring variable, an environmental condition, and any combination thereof.

18. A method for installing furring strips using fasteners, comprising the steps of:
selecting a deck or other square edged board for cladding;
using a board suitable table to determine if a board is suitable for cladding;
evaluating a building plan and construction for furring system requirements;
utilizing a furring system design matrix;
determining whether a furring option is compatible with a building design; and
selecting a structural screw or fastener for a furring back that is attached to a building structure.

19. The method of claim 18, wherein the furring system design matrix further includes allowing selection of wall constructions, sheathing thickness, and exterior insulation thickness.

20. The method of claim 19, further includes depending on a furring dimension and type of furring channel selecting a specific fastener.
